(19) United States
(12) Patent Application Publication
(10) Pub. No.: US 2018/0301575 A1
(43) Pub. Date: Oct. 18, 2018

(54) COMPOUND SEMICONDUCTOR SOLAR CELL AND METHOD FOR MANUFACTURING A FRONT ELECTRODE OF THE SOLAR CELL

(71) Applicant: LG ELECTRONICS INC., Seoul (KR)

(72) Inventors: Soohyun KIM, Seoul (KR); Gunho KIM, Seoul (KR); Jinhee PARK, Seoul (KR); Wonki YOON, Seoul (KR)

(73) Assignee: LG ELECTRONICS INC., Seoul (KR)

(21) Appl. No.: 15/948,231

(22) Filed: Apr. 9, 2018

(30) Foreign Application Priority Data
Apr. 12, 2017 (KR) 10-2017-0047315

(51) Int. Cl. H01L 31/0224

(52) U.S. Cl. CPC H01L 31/022433

(57) ABSTRACT

The disclosure relates to a compound solar cell and manufacturing method therefor.

According to one aspect of the subject matter described in this application, a method for manufacturing a front electrode of a compound solar cell comprises a step of forming a seed metal layer entirely on a front surface of a compound semiconductor layer, a step of forming a first mask layer covering the seed metal layer in the remaining region except a front electrode formation region, a step of forming a second mask layer on the first mask layer in the same pattern as the first mask layer, a step of forming an electrode metal layer on the seed metal layer in the front electrode formation region, a step of removing the seed metal layer under the first mask layer, and a step of forming a front electrode including the seed metal layer and the electrode metal layer positioned on the front electrode formation region by removing the first mask layer and the second mask layer.

### CROSS-REFERENCE TO RELATED APPLICATION

This application claims priority to and the benefit of Korean Patent Application No. 10-2017-0047315 filed in the Korean Intellectual Property Office on Apr. 12, 2017, the entire contents of which are incorporated herein by reference.

### BACKGROUND OF THE INVENTION

### (a) Field of the Invention

The disclosure relates to a compound solar cell and method for manufacturing a front electrode of the solar cell to reduce cost and improve productivity.

### (b) Description of the Related Art

A compound semiconductor is not made of a single element such as silicon (Si) and germanium (Ge) and is formed by a combination of two or more kinds of elements to operate as a semiconductor. Various kinds of compound semiconductors have been currently developed and used in various fields. The compound semiconductors are typically used for a light emitting element, such as a light emitting diode and a laser diode, and a solar cell using a photoelectric conversion effect, a thermoelectric conversion element using a Peltier effect, and the like.

A compound semiconductor solar cell uses a compound semiconductor in a light absorbing layer that absorbs solar light and generates electron-hole pairs. The light absorbing layer is formed using a III-V compound semiconductor such as GaAs, InP, GaAlAs and GaInAs, a II-VI compound semiconductor such as CdS, CdTe and ZnS, a compound semiconductor such as CuInSe2.

A compound semiconductor layer is very weak in heat. Therefore, when a compound semiconductor solar cell is manufactured, it is impossible to form the electrode by using the method of printing and sintering a conductive paste requiring a process at a high temperature (for example, 600° C. or higher)

In the prior art, a front electrode is formed by firstly forming a seed metal layer on a compound semiconductor layer and then secondly forming an electrode metal layer on the seed metal layer. Specifically, the prior art uses a first method requiring two patterning and two strip processes, or a second method requiring one patterning and one strip process.

In the first method, the process time is increased due to the two patterning processes and the two strip processes. In particular, precise alignment is required when forming the mask layer in the second patterning process. Therefore, the process for manufacturing a front electrode is difficult and complicated.

In the second method, since the electrode metal layer must be formed to be less than a certain thickness (for example, 3 μm) in order to achieve a satisfactory lift-off process using an organic solvent, it is difficult to use this first method. Further, since the electrode metal layer is also deposited on the seed metal layer on the mask layer, there is a problem that the material cost is greatly increased.

Accordingly, there is a need for a novel method capable of effectively forming a front electrode of a compound semiconductor solar cell.

### SUMMARY OF THE INVENTION

The present disclosure provides a method of manufacturing a front electrode of a compound semiconductor solar cell capable of lowering manufacturing costs and improving productivity and a compound semiconductor solar cell having a front electrode formed by the method.

According to one aspect, a method for manufacturing a front electrode of a compound solar cell includes forming a seed metal layer entirely on a front surface of a compound semiconductor layer, forming a first mask layer covering the seed metal layer in the remaining region except a front electrode formation region, forming a second mask layer on the first mask layer in the same pattern as the first mask layer, forming an electrode metal layer on the seed metal layer in the front electrode formation region, removing the seed metal layer under the first mask layer, and forming a front electrode including the seed metal layer and the electrode metal layer positioned on the front electrode formation region by removing the first mask layer and the second mask layer,

The first mask layer and the second mask layer are continuously formed by using an inkjet printing method or a screen printing method using a stencil mask.

The first mask layer and the second mask layer are simultaneously removed by an organic solvent comprising acetone.

When the seed metal layer under the first mask layer is removed, the seed metal layer under the first mask layer is removed by heat treatment at a temperature of 50 to 300° C. to react the etch component contained in the first mask layer with the seed metal layer.

In order to effectively remove the seed metal layer under the first mask layer, the thickness of the first mask layer is greater than the thickness of the seed metal layer.

When the seed metal layer under the first mask layer is removed using the first mask layer, the seed metal layer positioned in the front electrode formation region is formed such that the width of the lower surface in contact with the compound semiconductor layer is greater than the width of the upper surface opposite of the lower surface.

Therefore, the electrode metal layer can be formed such that the lower surface contacting the seed metal layer has a smaller width than the upper surface located on the opposite of the lower surface.

The seed metal layer is formed of a material selected from gold (Au), palladium (Pd), silver (Ag), titanium (Ti), and platinum (Pt) or an alloy thereof in a thickness of 5 to 100 nm by physical vapor deposition.

The first mask layer comprises an etching component selected from the group of potassium ion, iodine ion, and cyanide ion.

The first mask layer is formed to a thickness of 5 μm or less.

The thickness of the electrode metal layer is smaller than the sum of the thicknesses of the first mask layer and the second mask layer.

The second mask layer is formed to a thickness of 1 to 30 μm and the electrode metal layer is formed by plating a material selected from the group of copper (Cu), silver (Ag), and gold (Au) or an alloy thereof to a thickness of 1 to 30 μm.

In another aspect, a compound semiconductor solar cell includes a compound semiconductor layer and a front electrode of a grid shape positioned on a front surface of the compound semiconductor layer, wherein the front electrode includes a seed metal layer formed to have a width of a lower surface in contact with the compound semiconductor layer smaller than a width of upper surface opposite of the lower surface, and an electrode metal layer disposed on the seed metal layer.

The width of the lower surface in contact with the seed metal layer of the electrode metal layer is smaller than a width of the upper surface opposite of the lower surface.

The seed metal layer is formed of any one material selected from the group of gold (Au), palladium (Pd), silver (Ag), titanium (Ti), and platinum, and has a thickness of 5 to 100 nm.

The electrode metal layer is formed by plating a material selected from the group of copper (Cu), silver (Ag), and gold (Au) or an alloy thereof to a thickness of 1 to 30 μm.

In another aspect, a compound semiconductor solar cell includes a compound semiconductor layer and a front electrode of a grid shape positioned on a front surface of the compound semiconductor layer, wherein the front electrode includes a seed metal layer formed to have a width of a lower surface in contact with the compound semiconductor layer smaller than a width of upper surface opposite of the lower surface, and an electrode metal layer disposed on the seed metal layer.

The seed metal layer is formed of any one material selected from the group of gold (Au), palladium (Pd), silver (Ag), titanium (Ti), and platinum, and has a thickness of 5 to 100 nm.

The electrode metal layer is formed of any one material selected from the group of copper (Cu), silver (Ag), and gold (Au), and has a thickness of 1 to 30 μm.

According to the method for manufacturing the front electrode of the compound semiconductor solar cell according to the present invention, the first mask layer and the second mask layer can be continuously formed by the same printing method and the second mask layer can be simultaneously removed using an organic solvent.

Therefore, a separate precise alignment process for forming the second mask layer is not required, and the manufacturing process of the front electrode can be simplified.

Since the electrode metal layer can be formed only on the front electrode formation region without being formed on the second mask layer, the manufacturing cost of the compound semiconductor solar cell can be reduced, and the front metal layer can be formed thick, thereby effectively forming the front electrode of the large area solar cell.

### BRIEF DESCRIPTION OF THE DRAWINGS

FIG. 1 is a block diagram showing a method of manufacturing a front electrode of a compound semiconductor solar cell according to the present invention.

FIG. 2 is a process chart showing the method of manufacturing the front electrode shown in FIG. 1.

FIG. 3 is a cross-sectional view showing another embodiment of the front electrode manufactured by the manufacturing method shown in FIG. 1.

FIG. 4 is a perspective view of a compound semiconductor solar cell manufactured by the manufacturing method shown in FIG. 1.

### DETAILED DESCRIPTION OF THE EMBODIMENTS

Reference will now be made in detail to implementations of the invention examples of which are illustrated in the accompanying drawings. Since the invention may be modified in various ways and may have various forms, specific implementations are illustrated in the drawings and are described in detail in the specification. However, it should be understood that the invention are not limited to specific disclosed implementations, but include all modifications, equivalents and substitutes included within the spirit and technical scope of the invention.

The terms ‘first’, ‘second’, etc., may be used to describe various components, but the components are not limited by such terms. The terms are used only for the purpose of distinguishing one component from other components.

For example, a first component may be designated as a second component without departing from the scope of the implementations of the invention. In the same manner, the second component may be designated as the first component.

The term “and/or” encompasses both combinations of the plurality of related items disclosed and any item from among the plurality of related items disclosed.

When an arbitrary component is described as “being connected to” or “being linked to” another component, this should be understood to mean that still another component(s) may exist between them, although the arbitrary component may be directly connected to, or linked to, the second component.

On the other hand, when an arbitrary component is described as “being directly connected to” or “being directly linked to” another component, this should be understood to mean that no other component exists between them.

The terms used in this application are used to describe only specific implementations or examples, and are not intended to limit the invention. A singular expression can include a plural expression as long as it does not have an apparently different meaning in context.

In this application, the terms “include” and “have” should be understood to be intended to designate that illustrated features, numbers, steps, operations, components, parts or combinations thereof exist and not to preclude the existence of one or more different features, numbers, steps, operations, components, parts or combinations thereof, or the possibility of the addition thereof.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Unless otherwise specified, all of the terms which are used herein, including the technical or scientific terms, have the same meanings as those that are generally understood by a person having ordinary knowledge in the art to which the invention pertains.

The terms defined in a generally used dictionary must be understood to have meanings identical to those used in the context of a related art, and are not to be construed to have ideal or excessively formal meanings unless they are obviously specified in this application.

The following example implementations of the invention are provided to those skilled in the art in order to describe the invention more completely. Accordingly, shapes and sizes of elements shown in the drawings may be exaggerated for clarity.

Hereinafter, the present invention will be described with reference to the accompanying Figs.

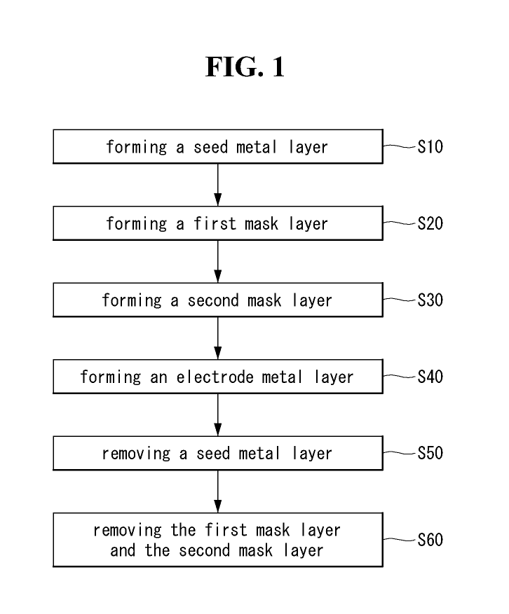

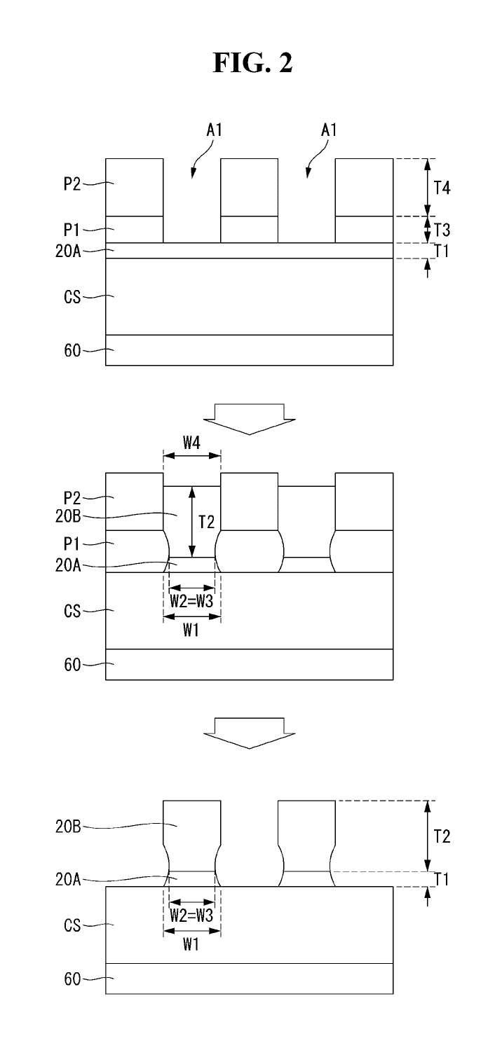

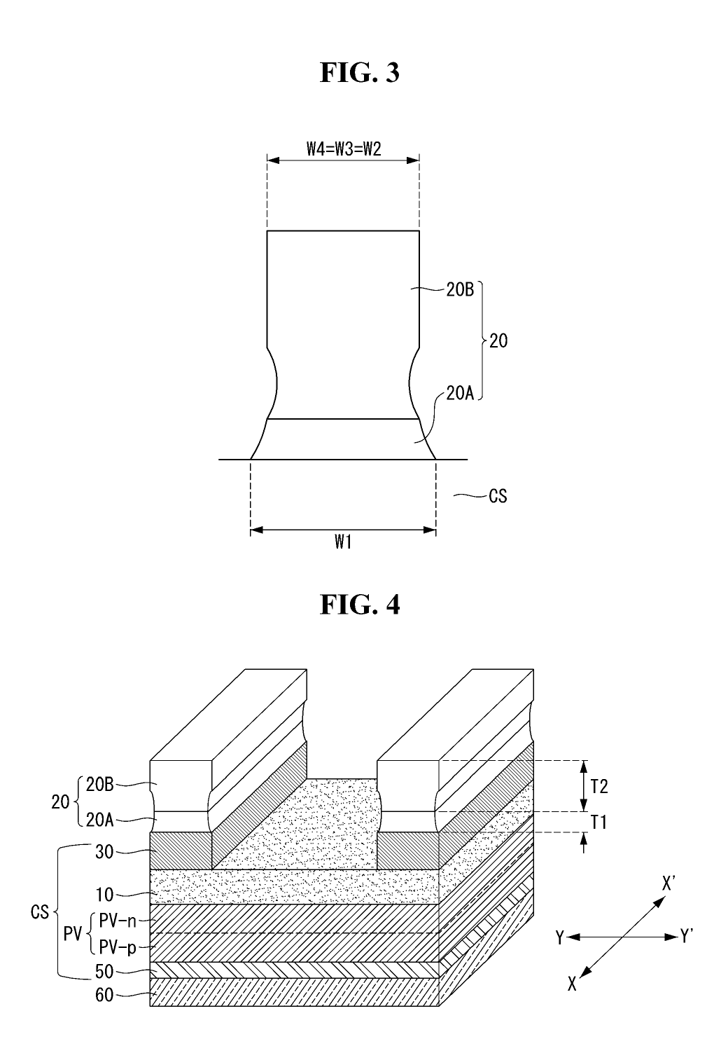

FIG. 1 is a block diagram showing a method of manufacturing a front electrode of a compound semiconductor solar cell according to the present invention. FIG. 2 is a process chart showing the method of manufacturing the front electrode shown in FIG. 1. FIG. 3 is a cross-sectional view showing another embodiment of the front electrode manufactured by the manufacturing method shown in FIG. 1. FIG. 4 is a perspective view of a compound semiconductor solar cell manufactured by the manufacturing method shown in FIG. 1.

First, a compound semiconductor solar cell manufactured by the manufacturing method of the present invention will be described with reference to FIG. 4.

A compound semiconductor solar cell of an implementation of the present invention may comprise a light absorbing layer PV, an window layer 10 positioned on a front surface of the light absorption layer, a first electrode 20 positioned on a front surface of the window layer 10, a first contact layer 30 positioned between the window layer 10 and the first electrode 20, an anti-reflection film 40 positioned on the window layer 10, a second contact layer 50 positioned on a rear surface of the light absorbing layer PV, and a second electrode positioned on a rear surface of the second electrode.

In the instance, at least one of the anti-reflection film 40 and the window layer 10 may be omitted, but a case where the anti-reflection film 40 and the window layer 10 are provided as shown in FIG. 4 will be described as an example.

The light absorbing layer PV may be formed to include a III-VI group semiconductor compound. For example, the light absorbing layer PV may be formed of an InGaP compound containing indium (In), gallium (Ga) and phosphide (P) or a GaAs compound containing gallium (Ga) and arsenic (As).

Hereinafter, a description will be given of an example in which the light absorption layer PV includes a GaAs compound.

The light absorbing layer PV may include a p-type semiconductor layer PV-p doped with an impurity of a first conductive type and an n-type semiconductor layer PV-n doped with an impurity of a second conductive type opposite the first conductive type.

The light absorbing layer PV may further include a back surface field layer.

The p-type semiconductor layer PV-p may be formed by doping a p-type impurity into the above-described compound, and the n-type semiconductor layer PV-n may be formed by doping an n-type impurity into the above-described compound.

Herein, the p-type impurity may be selected from carbon, magnesium, zinc or a combination thereof, and the n-type impurity may be selected from silicon, selenium, tellurium or a combination thereof.

The n-type semiconductor layer PV-n may be positioned in a region adjacent to the first electrode 120. The p-type semiconductor layer PV-p may be positioned in a region directly under the n-type semiconductor layer PV-n and may be positioned in a region adjacent to the second electrode 60.

That is, the interval between the n-type semiconductor layer PV-n and the front electrode 20 is smaller than the interval between the p-type semiconductor layer PV-p and the front electrode. The interval between the n-type semiconductor layer (PV-n) and the rear electrode 60 is larger than the interval between the p-type semiconductor layer (PV-p) and the rear electrode.

As a result, a p-n junction in which the p-type semiconductor layer PV-p and the n-type semiconductor layer PV-n are joined is formed in the light absorbing layer PV. The electron-hole pairs generated by the light are separated into electrons and holes by the internal potential difference formed by the p-n junction of the light absorbing layer PV so that electrons move toward the n-type semiconductor layer PV-n and holes move toward the p-type semiconductor layer PV-p.

Therefore, the holes generated in the light absorbing layer PV move to the second electrode 60 through the second contact layer 50 and the electrons generated in the light absorbing layer PV moves to the first electrode 20 through the window layer 10 and the first contact layer 30.

Alternatively, the p-type semiconductor layer PV-p may be positioned in a region adjacent to the first electrode 20 and the n-type semiconductor layer PV-n may be positioned in a region directly under the p-type semiconductor layer PV-p and may be positioned in a region adjacent to the second electrode 60. In this instance, the holes generated in the light absorbing layer PV move to the first electrode 20 through the first contact layer 30 and the electrons generated in the light absorbing layer PV move to the second electrode 60 through the second contact layer 50.

In the case where the light absorbing layer PV further includes the back surface field layer, the back surface field layer may have the same conductivity as the upper layer, that is, the n-type semiconductor layer PV-n or the p-type semiconductor layer PV-p and may be may be formed of the same material as the window layer 10.

In one example, the back surface field layer may be formed of AlGaInP.

In order to effectively block the movement of the charge (holes or electrons) to be moved toward the first electrode toward the second electrode, the back surface field layer is formed entirely on the rear surface of the upper layer directly contacting with the back surface field layer, that is, the n-type semiconductor layer PV-n or the p-type semiconductor layer PV-p.

That is, in the solar cell shown in FIG. 4, in the case where the back surface field layer is formed on the rear surface of the p-type semiconductor layer PV-p, the back surface field layer functions to block the movement of electrons toward the second electrode. In order to effectively block the movement of electrons toward the second electrode, the back surface field layer is positioned on the entire rear surface of the p-type semiconductor layer PV-p.

The light absorbing layer PV having such a structure may be formed on a mother substrate by a metal organic chemical vapor deposition (MOCVD) method, a molecular beam epitaxy (MBE) method, or any other suitable method for forming an epitaxial layer.

In the case of homogeneous junction, the p-type semiconductor layer PV-p and the n-type semiconductor layer PV-n may be made of the same material having the same band gap. Alternatively, in the case of heterojunction, the p-type semiconductor layer PV-p and the n-type semiconductor layer PV-n may be made of different materials having different band gaps.

The window layer 10 may be formed between the light absorbing layer PV and the first electrode 120 and may be formed by doping an impurity of the second conductivity type into a III-VI group semiconductor compound.

Here, aluminum (Al) is included in the window layer 10 in order to form the energy band gap of the window layer 10 higher than the energy band gap of the light absorption layer.

However, when the p-type semiconductor layer PV-p is positioned on the n-type semiconductor layer PV-n and the window layer 10 is positioned on the p-type semiconductor layer PV-p, the window layer 10 may include a first conductivity type (i.e., a p-type) impurity.

However, the window layer 10 may not contain n-type or p-type impurities.

The window layer 10 serves to passivate the front surface of the light absorbing layer PV. Therefore, when the carrier (electrons or holes) moves to the surface of the light absorbing layer PV, the window layer 110 can prevent the carriers from recombining on the surface of the light absorbing layer PV.

Since the window layer 10 is disposed on the front surface (i.e., light incident surface) of the light absorbing layer PV, in order to prevent light incident on the light absorbing layer PV from being absorbed, the window layer 10 may have an energy band gap higher than the energy band gap of the light absorbing layer PV.

The anti-reflection film may be located on the entire surface of the window layer 10 except the region where the first electrode 20 and/or the first contact layer 30 are located.

Alternatively, the anti-reflection film may be disposed on the first contact layer 30 and the first electrode 20 as well as the exposed window layer 10.

In this instance, the compound semiconductor solar cell may further include at least one bus bar electrodes physically connecting the plurality of first electrodes 20, and the bus bar electrode may not be covered by the anti-reflection film 40 and can be exposed to the outside.

The anti-reflection film 40 having such a structure may include magnesium fluoride, zinc sulfide, titanium oxide, silicon oxide, derivatives thereof, or a combination thereof.

The front electrode 20 may be formed to extend in the first direction X-X′, and a plurality of the front electrodes 20 may be spaced apart from each other along a second direction Y-Y′ orthogonal to the first direction.

The front electrode 20 may include a seed metal layer 20A which is formed of a material selected from gold (Au), palladium (Pd), silver (Ag), titanium (Ti), and platinum (Pt) or an alloy thereof in a thickness of 5 to 100 nm by physical vapor deposition, and an electrode metal layer 20B which is formed by plating a material selected from the group of copper (Cu), silver (Ag), and gold (Au) or an alloy thereof to a thickness of 1 to 30 μm.

In this case, for example, the seed metal layer 20A may be formed such that the width W1 of the lower surface in contact with the compound semiconductor layer CS is larger than the width W2 of the upper surface located on the opposite side of the lower surface and the electrode metal layer 20B may be formed to have a width W3 of the lower surface contacting the seed metal layer 20A smaller than a width W4 of the upper surface located on the opposite side of the lower surface.

As described, the cross-sectional shape of the seed metal layer 20A, in which the width W1 of the lower surface is formed to be larger than the width W2 of the upper surface, is a characteristic configuration generated only by the manufacturing method of the present invention for removing the seed metal layer located under the electrode metal layer 20B by using the first mask layer.

That is, when the front electrode is formed by the conventional manufacturing method, the width of the upper surface of the seed metal layer is formed to be larger than the width of the lower surface. However, the front electrode is formed by the manufacturing method of the present invention, the seed metal layer is formed such that the width of the lower surface is larger than the width of the upper surface.

Similarly, the cross-sectional shape of the electrode metal layer 20B in which the width W4 of the upper surface is larger than the width W3 of the lower surface also is the characteristic configuration of the present invention.

The reason why the width of the lower surface of the seed metal layer is formed larger than the width of the upper surface and the reason why the width of the upper surface of the electrode metal layer is formed to be larger than the width of the lower surface will be described with reference to FIGS. 1 and 2, when a manufacturing method of the solar cell will be described in detail.

The width W1 of the lower surface of the seed metal layer 20A and the width W4 of the upper surface of the electrode metal layer 20B may be substantially equal to each other and the width of the upper surface of the seed metal layer 20A W2 and the width W3 of the lower surface of the electrode metal layer 20B may be substantially equal to each other (see FIGS. 2 and 4).

Thus, the width W2 or W3 of the interface between the seed metal layer 20A and the electrode metal layer 20B may be smaller than the width W1 of the lower surface of the seed metal layer 20A and the width W4 of the upper surface of the electrode metal layer 20B.

That is, the width of the seed metal layer 20A increases from the upper surface toward the lower surface, and the width W1 of the lower surface of the seed metal layer 20A is greater than the width W2 of the upper surface. Therefore, since the contact area between the seed metal layer 20A and the front contact layer is increased, electrical characteristics are improved.

However, the width W2 of the upper surface of the seed metal layer 20A and the width W3 of the lower surface of the electrode metal layer 20B may not be equal to each other.

In this case, as shown in FIG. 3, The width W2 of the upper surface of the seed metal layer 20A, the width W3 of the lower surface of the electrode metal layer 20B and the width W4 of the upper surface of the electrode metal layer 20B may be substantially equal to each other, The width W1 of the lower surface of the seed metal layer 20A may be larger than the width W2 of the upper surface of the seed metal layer 20A.

The first contact layer 30 positioned between the window layer 10 and the front electrode 20 is formed by doping the second impurity with a dopant concentration higher than the impurity doping concentration of the window layer 10 into the III-V compound semiconductor.

The front contact layer 30 forms an ohmic contact between the window layer 10 and the front electrode 20. That is, when the front electrode 20 directly contacts the window layer 10, the ohmic contact between the front electrode 20 and the light absorbing layer PV is not well formed because the impurity doping concentration of the window layer 10 is low. Therefore, the carrier moved to the window layer 10 cannot move to the front electrode 20 and can be destroyed.

However, when the front contact layer 30 is formed between the front electrode 20 and the window layer 10, since the front contact layer 30 forms an ohmic contact with the front electrode 20, the carrier is smoothly moved and the short circuit current density Jsc of the compound semiconductor solar cell increases. Thus, the efficiency of the solar cell can be further improved.

In order to form an ohmic contact with the front electrode 20, the doping concentration of the second dopant doped in the front contact layer 30 may be greater than the doping concentration of the second dopant doped in the window layer 10.

The front contact layer 30 is formed in the same shape as the first electrode 20.

A rear contact layer 50 disposed on the rear surface of the p-type semiconductor layer PV-p of the light absorbing layer PV is entirely located on the rear surface of the light absorbing layer PV and 150 may be formed by doping the first conductive type impurity into the III-VI group semiconductor compound at a doping concentration higher than that of the p-type semiconductor layer PV-p.

The second contact layer 50 forms an ohmic contact with the rear electrode 60, so that the short circuit current density Jsc of the compound semiconductor solar cell can be further improved. Thus, the efficiency of the solar cell can be further improved.

The thickness of the front contact layer 30 and the thickness of the rear contact layer 50 may each be 100 nm to 300 nm. For example, the front contact layer 30 may be formed with a thickness of 100 nm and the rear contact layer 50 may be formed with a thickness of 300 nm.

The rear electrode 60 positioned on the rear surface of the second contact layer 50 may be a sheet-like conductive layer positioned entirely on the rear surface of the light absorbing layer PV, different from the front electrode 20. That is, the rear electrode 60 may be referred to as a sheet electrode located on the entire rear surface of the light absorbing layer PV.

At this time, the second electrode 60 may be formed in the same planar area as the light absorbing layer PV.

Hereinafter, a method for manufacturing a front electrode of a compound semiconductor solar cell will be described with reference to FIGS. 1 and 2.

According to one embodiment, a method for manufacturing a front electrode of a compound solar cell comprises a step S10 of forming a seed metal layer 20A entirely on a front surface of a compound semiconductor layer CS, a step S20 of forming a first mask layer P1 covering the seed metal layer 20A in the remaining region except a front electrode formation region A1, a step S30 of forming a second mask layer P2 on the first mask layer P1 in the same pattern as the first mask layer P1, a step S40 of forming an electrode metal layer 20B on the seed metal layer 20A in the front electrode formation region A1, a step S50 of removing the seed metal layer 20A under the first mask layer P1, and a step S60 of forming a front electrode 20 including the seed metal layer 20A and the electrode metal layer 20B positioned on the front electrode formation region A1 by removing the first mask layer P1 and the second mask layer P2.

The compound semiconductor layer CS may be formed by forming a sacrificial layer on one surface of a mother substrate serving as a base for providing a suitable lattice structure in which the light absorbing layer PV is formed, growing various layers formed of compound semiconductors (For example, a rear contact layer, a back surface field layer, a p-type semiconductor layer, an n-type semiconductor layer, a window layer, and a front contact layer) on a sacrificial layer, removing the sacrificial layer by an epitaxial lift off (ELO) process, and separating the various layers from the mother substrate.

Accordingly, the compound semiconductor layer CS may include the various layers mentioned above, for example, the rear contact layer, the back surface field layer, the p-type semiconductor layer, the n-type semiconductor layer, the window layer and the front contact layer.

The sacrificial layer and the compound semiconductor layer CS may be formed by a metalorganic chemical vapor deposition (MOCVD) method, a molecular beam epitaxy (MBE) method, or any other suitable method for forming an epitaxial layer.

At this time, the mother substrate has a size capable of manufacturing a plurality of compound semiconductor solar cells, and the compound semiconductor layer (CS) formed on the sacrificial layer of the mother substrate has the same size as the mother substrate.

The front electrode 20 may be formed on the front surface of the compound semiconductor layer CS after the rear electrode 60 is formed and the carrier substrate is attached to the rear surface of the rear electrode 60.

The front electrode 20 is formed on the front surface of the compound semiconductor layer CS after the rear electrode 60 is formed on the rear surface of the compound semiconductor layer CS according to the above-described method.

In order to form the front electrode 20, a seed metal layer 20A is entirely formed on the front surface of the compound semiconductor layer CS (S10).

The seed metal layer 20A is formed of a material selected from gold (Au), palladium (Pd), silver (Ag), titanium (Ti), and platinum (Pt) or an alloy thereof in a thickness of 5 to 100 nm by physical vapor deposition.

Next, a first mask layer P1 covering the seed metal layer 20A except for the front electrode formation region A1 is formed (S20), and The second mask layer P2 is formed on the first mask layer P1 in the same pattern as the first mask layer P1 (S30).

The first mask layer P1 and the second mask layer P1 may be continuously formed by using an inkjet printing method or a screen printing method using a stencil mask.

The first mask layer P1 may be formed of an etching paste pattern including any one of potassium ion, iodine ion, and cyanide ion capable of removing a material for forming a seed metal layer 20A such as a material selected from gold (Au), palladium (Pd), silver (Ag), titanium (Ti), and platinum (Pt) or an alloy thereof.

In order to effectively remove the seed metal layer 20A under the first mask layer P1, the thickness T3 of the first mask layer P1 is formed thicker than the thickness T1 of the seed metal layer 20A.

As an example, the first mask layer P1 may be formed to have a thickness T3 of 5 μm or less.

The second mask layer P2 may be formed using a conventional photoresist pattern and may have a thickness T4 of 1 to 30 μm.

The first mask layer P1 and the second mask layer P2 may be simultaneously removed using an organic solvent containing acetone.

After the first mask layer P1 and the second mask layer P2 are formed, an electrode metal layer 20B is formed on the seed metal layer 20A of the front electrode formation region A1 (S40).

The electrode metal layer 20B can be formed by plating a material selected from copper (Cu), silver (Ag), and gold (Au) or an alloy thereof to have a thickness (T2) of 1 to 30 μm.

In this case, the thickness T2 of the electrode metal layer 20B may be smaller than the sum T3+T4 of the thickness T3 of the first mask layer P1 and the thickness T4 of the second mask layer P2, and the sum T1+T2 of the thickness T1 of the seed metal layer 20A and the thickness T2 of the electrode metal layer 20B may be smaller than the sum T3+T4 of the thickness T3 of the first mask layer P1 and the thickness T4 of the second mask layer P2.

After the electrode metal layer 20B is formed, heat treatment is performed at a temperature of 50 to 300° C.

When the heat treatment is performed, the seed metal layer 20A under the first mask layer P1 is etched by reacting the first mask layer P1 with the seed metal layer 20A (S50).

When the seed metal layer 20A under the first mask layer P1 is removed by using the first mask layer P1, the seed metal layer 20A located in the front electrode formation region A1 can be removed to have the width W1 of the lower surface contacting the layer CS greater than the width W2 of the upper surface located on the opposite side of the lower surface.

When the seed metal layer 20A under the first mask layer P1 is removed using the first mask layer P1, the portion of the electrode metal layer 20b in contact with the first mask layer P1 can be partially removed.

Therefore, the electrode metal layer 20B can be formed so that the width W3 of the lower surface in contact with the seed metal layer 20A is smaller than the width W4 of the upper surface located on the opposite side of the lower surface.

In this case, the width W1 of the lower surface of the seed metal layer 20A and the width W4 of the upper surface of the electrode metal layer 20B may be equal to each other. The width W2 and the width W3 of the lower surface of the electrode metal layer 20B may be equal to each other.

When the seed metal layer 20A under the first mask layer P1 is removed using the first mask layer P1 as described above, the front electrode 20 is formed such that width W2 or W3 of the interface between the seed metal layer 20A and the electrode metal layer 20B is narrower than the width of the lower surface of the seed metal layer 20A and the width of the upper surface of the electrode metal layer 20B.

However, the width W2 of the upper surface of the seed metal layer 20A and the width W3 of the lower surface of the electrode metal layer 20B may be different from each other.

In this case, as shown in FIG. 3, the width W2 of the upper surface of the seed metal layer 20A, the width W3 of the lower surface of the electrode metal layer 20B and the width W4 of the upper surface of the electrode metal layer 20B may be substantially equal to each other. In addition, the width W1 of the lower surface of the seed metal layer 20A may be larger than the width W2 of the upper surface of the seed metal layer 20A.

Subsequently, the first mask layer P1 and the second mask layer P2 are simultaneously removed using an organic solvent containing acetone (S60).

When the first mask layer P1 and the second mask layer P2 are removed, the front electrode 20 of the grid pattern including the seed metal layer 20A and the electrode metal layer 20B is formed in the front electrode forming region A1 of the compound semiconductor layer CS.

Meanwhile, the front contact layer 30 provided in the compound semiconductor solar cell may be removed by an etching process using the front electrode 20 as a mask before or after a scribing step. Accordingly, the front contact layer 30 can be formed in the same pattern as the front electrode 20, as shown in FIG. 3.

According to the method for manufacturing the front electrode of the compound semiconductor solar cell according to the present invention, the first mask layer and the second mask layer can be continuously formed by the same printing method and can be simultaneously removed using an organic solvent.

Therefore, the manufacturing method of the present invention does not require a separate precise alignment work for forming the second mask layer, so that the manufacturing process of the front electrode can be simplified.

According to the manufacturing method of the present invention, since the electrode metal layer can be formed only on the front electrode formation region without being formed on the second mask layer, the material cost of the electrode metal layer can be lowered, and the manufacturing cost of the compound semiconductor solar cell can be effectively reduced. In addition, since the front metal layer can be formed thick, the front electrode of the large-area solar cell can be effectively formed.

Although the compound semiconductor solar cell has been described as having one light absorbing layer as an example, a plurality of light absorbing layers may be formed.

In this case, the lower light absorbing layer may include a GaAs compound that absorbs light in a long wavelength band to perform photoelectric conversion, and the upper light absorbing layer may include a GaInP compound that absorbs light in a short wavelength band to photoelectrically convert the light, and a tunnel junction layer may be positioned between the lower light absorption layer and the lower light absorption layer.

Further, an intrinsic semiconductor layer may be further formed between the p-type semiconductor layer and the n-type semiconductor layer of the light absorption layer.

What is claimed is:

1. A method for manufacturing a front electrode of a compound solar cell, the method comprising:
forming a seed metal layer entirely on a front surface of a compound semiconductor layer;
forming a first mask layer covering the seed metal layer in the remaining region except a front electrode formation region;
forming a second mask layer on the first mask layer in the same pattern as the first mask layer;
forming an electrode metal layer on the seed metal layer in the front electrode formation region;
removing the seed metal layer under the first mask layer; and
forming a front electrode including the seed metal layer and the electrode metal layer positioned on the front electrode formation region by removing the first mask layer and the second mask layer,

2. The method of claim 1, wherein the first mask layer and the second mask layer are continuously formed by using an inkjet printing method or a screen printing method using a stencil mask.

3. The method of claim 1, wherein the first mask layer and the second mask layer are simultaneously removed by an organic solvent comprising acetone.

4. The method of claim 1, wherein the seed metal layer under the first mask layer is removed by heat treatment at a temperature of 50 to 300° C. to react the etch component contained in the first mask layer with the seed metal layer.

5. The method of claim 1, wherein the thickness of the first mask layer is greater than the thickness of the seed metal layer.

6. The method of claim 5, wherein the seed metal layer positioned in the front electrode formation region is formed such that the width of the lower surface in contact with the compound semiconductor layer is greater than the width of the upper surface opposite of the lower surface.

7. The method of claim 6, wherein the electrode metal layer located in the front electrode forming region is formed to have a lower width in contact with the seed metal layer than in an upper surface located opposite to the lower surface.

8. The method of claim 6, wherein the seed metal layer is formed of a material selected from gold (Au), palladium (Pd), silver (Ag), titanium (Ti), and platinum (Pt) or an alloy thereof in a thickness of 5 to 100 nm by physical vapor deposition.

9. The method of claim 8, wherein the first mask layer comprises an etching component selected from the group of potassium ion, iodine ion, and cyanide ion.

10. The method of claim 6, wherein the first mask layer is formed to a thickness of 5 μm or less.

11. The method of claim 6, wherein the thickness of the electrode metal layer is smaller than the sum of the thicknesses of the first mask layer and the second mask layer.

12. The method of claim 11, wherein the second mask layer is formed to a thickness of 1 to 30 μm.

13. The method of claim 12, wherein the electrode metal layer is formed by plating a material selected from the group of copper (Cu), silver (Ag), and gold (Au) or an alloy thereof to a thickness of 1 to 30 μm.

14. A compound semiconductor solar cell, comprising:
a compound semiconductor layer; and
a front electrode of a grid shape positioned on a front surface of the compound semiconductor layer,
wherein the front electrode includes a seed metal layer formed to have a width of a lower surface in contact with the compound semiconductor layer smaller than a width of upper surface opposite of the lower surface, and an electrode metal layer disposed on the seed metal layer.

15. The compound semiconductor solar cell of claim 14, wherein a width of the lower surface in contact with the seed metal layer of the electrode metal layer is smaller than a width of the upper surface opposite of the lower surface.

16. The compound semiconductor solar cell of claim 15, wherein the seed metal layer is formed of any one material selected from the group of gold (Au), palladium (Pd), silver (Ag), titanium (Ti), and platinum, and has a thickness of 5 to 100 nm.

17. The compound semiconductor solar cell of claim 16, wherein the electrode metal layer is formed of any one material selected from the group of copper (Cu), silver (Ag), and gold (Au), and has a thickness of 1 to 30 μm.

18. A compound semiconductor solar cell, comprising:
a compound semiconductor layer; and
a front electrode of a grid shape positioned on a front surface of the compound semiconductor layer,
Wherein the front electrode includes a seed metal layer in contact with the compound semiconductor layer and an electrode metal layer positioned on the seed metal layer, and
a width of the interface between the seed metal layer and the electrode metal layer is narrower than the width of the lower surface of the seed metal layer and the width of the upper surface of the electrode metal layer.

19. The compound semiconductor solar cell of claim 18, wherein the seed metal layer is formed of any one material selected from the group of gold (Au), palladium (Pd), silver (Ag), titanium (Ti), and platinum, and has a thickness of 5 to 100 nm.

20. The compound semiconductor solar cell of claim 19, wherein The electrode metal layer is formed of any one material selected from the group of copper (Cu), silver (Ag), and gold (Au), and has a thickness of 1 to 30 μm.
